(19) United States
(12) Patent Application Publication
(10) Pub. No.: US 2014/0233744 A1
(43) Pub. Date: Aug. 21, 2014

(54) AUDIO PROCESSING AND ENHANCEMENT SYSTEM

(71) Applicant: ACTIWAVE AB, Solna (SE)

(72) Inventors: Pär Gunnars Risberg, Solna (SE); Landy Toth, Newton, PA (US)

(21) Appl. No.: 14/347,097

(22) PCT Filed: Sep. 26, 2012
(86) PCT No.: PCT/US2012/057223

§ 371 Date: Mar. 25, 2014

Related U.S. Application Data
(60) Provisional application No. 61/539,025, filed on Sep. 26, 2011.

(51) Int. Cl. H03G 9/00

(52) U.S. Cl. CPC H03G 9/005
USPC 381/61; 381/120; 700/94

(57) ABSTRACT

A system and method for enhancing the audio experience on a consumer electronic device is disclosed. A system for enhancing the audio experience on a consumer electronic device including a parametrically configurable processing block is disclosed. An all-digital audio enhancement system suitable for embedding into a low cost, low power application specific integrated circuit is disclosed. A method for configuring an audio enhancement system on a consumer electronic device is also disclosed.

### CROSS-REFERENCE TO RELATED APPLICATION

The present application is an international application which claims benefit of and priority to U.S. Provisional Application Ser. No. 61/539,025 filed on Sep. 26, 2011, entitled “Audio Processing and Enhancement System”, by Pär Gunnars Risberg et al., the entire contents of which are incorporated by reference herein for all purposes.

### BACKGROUND

1. Technical Field

The present disclosure is directed to audio processing within consumer products. More particularly, the invention relates to systems and methods for enhancing audio output from consumer electronic devices. More particularly, the invention relates to systems and methods for enhancing audio from devices with highly constrained and suboptimal acoustic form factors.

2. Background

Mobile technologies and consumer electronic devices (CED) continue to expand in use and scope throughout the world. In parallel with continued proliferation, there is rapid technical advance of device hardware and components, leading to increased computing power and incorporation of new peripherals onboard a device along with reductions in device size, power consumption, etc. Most devices, such as mobile phones, tablets, and laptops, include audio communication systems and particularly one or more loudspeakers to interact with and stream audio data to a user.

Every device has an acoustic signature, meaning the audible characteristics of a device dictated by its design that influence the sound generated by the device. The acoustic signature of the device may significantly influence the audio experience of a user.

Audio experience is one of many factors considered in the design of consumer electronic devices. Often, the quality of audio systems, loudspeakers, etc. are compromised in favor of other design factors such as cost, visual appeal, form factor, screen real-estate, case material selection, hardware layout, and assembly considerations amongst others.

Many of these competing factors are favored at the expense of the audio quality, as determined by the audio drivers, component layout, loudspeakers, material and assembly considerations, housing design, etc.

Adding to the design challenges, the usage cases for such devices can be complex. Users may demand high quality audio experiences during a wide range of usage scenarios. Such examples include listening to the same audio device as it is placed against an ear, or on a table, couch, lap, in various rooms, amongst groups of users, within automobiles, etc.

Although many audio systems provide user-adjustable equalizers and other sound-enhancing options, these products merely make rudimentary adjustments to the audio signals being processed. That is, these products do not correct for deficiencies in the acoustic system and thus compensate for the actual sound that is propagated into the listening environment. Moreover, many existing sound-enhancing products are embodied in software programs requiring considerable resources from processors that are already heavily constrained.

The summation of these factors often leads to a significantly underwhelming audio experience for a user and an overall reduction in use of the devices in certain, otherwise satisfying scenarios.

Therefore, there is a need to provide an enhanced audio experience for users of mobile technologies and consumer electronic devices.

### SUMMARY

One objective of this disclosure is to provide a system and method for enhancing audio output from a consumer electronic device.

Another objective is to provide a system for enhancing audio from a form-factor constrained consumer electronic device.

Yet another objective is to provide an audio enhancement system for a consumer electronic device with substantially minimized hardware, software and/or power requirements.

Yet another objective is to seamlessly enhance audio streaming through a consumer electronic device.

Yet another objective is to compensate out the acoustic signature of a consumer electronic device to enhance and/or standardize audio output from the device.

The above objectives are wholly or partially met by devices, systems, and methods according to the appended claims in accordance with the present disclosure. Features and aspects are set forth in the appended claims, in the following description, and in the annexed drawings in accordance with the present disclosure.

According to a first aspect, there is provided a system for enhancing audio in a consumer electronic device. The system includes a parametrically configurable processing (PCP) block, and a digital driver (DD) block. The PCP block is configured to accept one or more audio signals (e.g. a digital audio signal) from an audio signal source (e.g. a processor, an audio streaming device, an audio feedback device, a wireless transceiver, an ADC, an audio decoder circuit, etc.) and to provide one or more enhanced signals to the DD block. The PCP block generally includes one or more transfer functions that relate the input audio signals to the enhanced audio signals. The DD block is configured to provide output signals suitable for driving a transducer (e.g. a loudspeaker) or the input to a transducer module (e.g. a passive filter circuit, an amplifier, a de-multiplexer, a switch array, a serial communication circuit, a parallel communication circuit, a FIFO communication circuit, a charge accumulator circuit, etc.). The DD block may include a pulse width modulator (PWM). In aspects, the PCP block and/or the DD block may receive sensor data for feed-back purposes. In one non-limiting example sensor data may be a current and/or voltage reading relating to the operation of the transducer.

The system may include an arbitrary or asynchronous sample rate conversion (ASRC) block. The ASRC block may be integrated into the system between the input and the PCP block, between the PCP block and the DD block, or integrated into either the PCP block or the DD block. The ASRC block may be configured to accept one or more audio signals (e.g. a digital audio signal) of arbitrary sample rate from an audio signal source (e.g. a processor, an audio streaming device, an audio feedback device, a wireless transceiver, an ADC, an audio decoder circuit, the PCP block, etc.), and to produce one or more converted signals with a different sample rate. Depending on the particular implementation, the ASRC block may be configured to deliver one or more converted signals to the PCP block, the DD block or to elements within either block.

The system may be embedded in an application specific integrated circuit (ASIC) or be provided as a hardware descriptive language block (e.g. VHDL, Verilog, etc.) for integration into a system on chip (SoC), an application specific integrated circuit (ASIC), a field programmable gate array (FPGA), or a digital signal processor (DSP) integrated circuit. The PCP block may also be implemented in software. The system may be an all-digital hardware implementation. An all-digital implementation may be advantageous to reduce the hardware footprint, reduce power consumption, reduce production costs, and increase the number of integrated circuit processes into which the system may be implemented.

In aspects, the PCP block may include and/or may be configured to accept one or more parameters that influence at least a portion of the transfer function between one or more converted signals to one or more enhanced signals. The PCP block may include a memory element for storage of the parameters. Alternatively, additionally, or in combination, one or more parameters may be provided in a separately located memory element, loaded into the PCP block during power-up, or hardware encoded directly into a VHDL implementation of the system. The parameters may be loaded from a network (e.g. over the internet, from the cloud, etc.).

In aspects, the PCP block may be configured to provide such functions as FIR filtering, IIR filtering, warped FIR filtering, transducer artifact removal, disturbance rejection, user specific acoustic enhancements, user safety functions, emotive algorithms, psychoacoustic enhancement, signal shaping, single or multi-band compression, expanders or limiters, watermark superposition, spectral contrast enhancement, spectral widening, frequency masking, quantization noise removal, power supply rejection, crossovers, equalization, amplification, driver range extenders, power optimization, linear or non-linear feedback or feed-forward control systems, and the like. The PCP block may include one or more of the above functions, either independently or in combination. One or more of the included functions may be configured to depend on one or more of the parameters. In aspects, the PCP-block may include a non-linear feedback control system including an observer and the audio system may include a means for producing one or more feedback signals. The observer may be configured to accept one or more of the feedback signals or signals generated therefrom and to generate one or more of the estimated states from one or more of the feedback signals and one or more of the control signals. In aspects, the observer may include a nonlinear observer, a sliding mode observer, a Kalman filter, an adaptive filter, a least means square adaptive filter, an augmented recursive least square filter, an extended Kalman filter, ensemble Kalman filter, high order extended Kalman filters, a dynamic Bayesian network. In one non-limiting example, the observer may include an unscented Kalman filter or an augmented unscented Kalman filter to generate one or more of the estimated states.

In aspects, the audio enhancement system may include a protection block, the protection block configured to analyze one or more of the input signals, the estimated states and/or the control signals and to modify the control signals based upon the analysis so as to limit the temperature and/or the voice coil excursion of an associated loudspeaker element. In aspects, the audio enhancement system may accept a voltage and/or current from the loudspeaker element as input into the observer.

In aspects, the parameters may be pre-configured during the design, validation, or testing process of the consumer electronic device. Alternatively, additionally, or in combination, the parameters may be pre-configured, tweaked or optimized during the manufacturing, quality control, and/or testing processes of the consumer electronic device. Alternatively, additionally, or in combination, the parameters may be uploaded to the consumer electronic device during a firmware upgrade or through a software update process.

In aspects, one or more of the parameters may be dependent on the particular design of the consumer electronic device into which the system may be integrated and/or to which the system may be interfaced.

In aspects, placement of an ASRC block between the input and the PCP block may be advantageous for many applications, but particularly in memory constrained devices. In one non-limiting example, an ASRC block may allow for the use of a single set of parameters that are irrespective of the sampling rate of the input audio signal, for the rest of the processing. An ASRC placed at the input to the system may also remove jitter from the input audio signal, which may be advantageous for enhancing the sound from some types of input sources.

In aspects, the DD block may be pre-configured and/or pre-selected to drive a range of electroacoustic transducers (e.g. electromagnetic, thermoacoustic, electrostatic, magnetostrictive, ribbon, arrays, electroactive material transducers, etc.). The DD block may be configured to provide a power efficient PWM signal for the transducer, or to the input of a transducer module (e.g. a passive filter circuit, an amplifier, a de-multiplexer, a switch array, a serial communication circuit, a parallel communication circuit, a FIFO communication circuit, a charge accumulator circuit, etc.). The PCP block may include a power optimization function, dependent on one or more of the parameters. The power optimization function may be configured via one or more of the parameters to optimize power transfer from the DD block to the transducer.

In aspects, the system may include a feedback block configured to provide a feedback signal. Alternatively, additionally, or in combination, any block within the system may be configured to provide one or more feedback signals. The feedback signals may be provided to the audio signal source, a supervisor, and/or a processor. The feedback signal may be a quantitative metric related to processing efficiency of the audio signal(s), status of one or more aspects of a block or the system, power consumption of one or more blocks in the system, changes in the transducer characteristics (e.g. voice coil resistance, input impedance, impedance spectrum, excursion parameter, etc.). The feedback signal may include information suitable for tweaking and/or optimizing one or more of the parameters. In aspects, the feedback signal may be used as part of a nonlinear control system (i.e. included in the PCB block), a loudspeaker protection algorithm, or the like.

In aspects, the system may be configured to accept one or more control signals from the audio signal source, a supervisor, and/or a processor. The system may be configured to respond to the control signal to reduce power consumption, enter a low-power state, run a diagnostic test, or the like. The control signals may provide a service (e.g. a timer, a flag, etc.) to one or more of the blocks in the system.

One or more of the blocks in the system may be adjustable between states of efficient audio processing and high audio quality. The degree of adjustment between states may be set by the control signal.

In aspects, the DD block may include a diagnostic function configured to analyze the one or more transducers included in the consumer electronic device. Upon receipt of a control signal, the diagnostic function may be configured to enable and monitor the audio input signal, the audio output signal, a transducer performance metric (e.g. temperature, input impedance, membrane movement [i.e. excursion], etc.), and/or an audio output (e.g. by means of an onboard microphone, etc.). The diagnostic function may be configured to superimpose one or more diagnostic signals (e.g. a chirp signal, an impulse signal, etc.) onto the output signal. The diagnostic function may be configured to return the results of such diagnostic testing to the audio source, a supervisor, or a processor located on the device or perhaps in the cloud, on a network server, etc. Alternatively, or in combination, the diagnostic function may be configured to store a transducer metric, calculated from the diagnostic test (e.g. an impulse response, etc.). The diagnostic function may be configured to compare a previously saved transducer metric to a presently calculated transducer metric and generate a feedback signal suitable for deciding whether or not to update the audio enhancement system (e.g. update the parameters of the PCP block, etc.).

In aspects, the PCP block may be configured to provide echo cancellation, environmental artifact correction, reverb reduction, beam forming, auto calibration, stereo widening, virtual surround sound, virtual center speaker, virtual sub-woofer (by digital bass enhancement techniques), noise suppression, sound effects, or the like.

In aspects the PCP block may be configured to integrate ambient sounds onto an audio signal, such as by modifying the audio input signal with an ambient environmental characteristic (e.g. adjusting reverb, echo, etc.) and/or superimposing ambient sound effects to the audio input signal akin to an environmental setting (e.g. a live event, an outdoor setting, a concert hall, a church, a club, a jungle, a shopping mall, a conference setting, an elevator, a conflict zone, an airplane cockpit, a department store radio network, etc.).

Additionally or in combination, the PCP block may be configured to accept and respond to a location based control signal from the audio signal source, a processor, or a network (e.g. the internet, the cloud, a LAN, etc.). The PCP block may alter the ambient sound effects based on the location-based control signal. The system may include a memory element suitable for storing the ambient sound effects. The system may be configured to receive ambient sound effects from the audio signal source, a processor, a network, or the like.

In aspects, the ambient sound effects may include specific information about a user, such as name, preferences, etc. The ambient sound effects may be used to securely superimpose personalized information (e.g. greetings, product specific information, directions, watermarks, handshakes, etc.) into an audio stream.

According to another aspect there is provided, a system for enhancing audio in a consumer electronic device, including a PCP block, the consumer electronic device or the system having a limited number of loudspeakers (e.g. 1 or 2). The system may be configured to accept a 5.1 surround sound signal, or the like, and to deliver it to the PCP block. The PCP block may include functions to create a virtual center speaker and a virtual sub-woofer from the 5.1 surround sound signal and add them to the enhanced audio signal. The PCP block may include one or more virtual sound processing functions to further reduce the number of necessary loudspeakers to 2. The PCP block may be configured to deliver the enhanced audio signal to a DD block, which is configured to drive the limited number of loudspeakers. This implementation may be advantageous to improve audio quality in low cost and highly constrained consumer electronic devices.

In aspects, the system may be implemented in a wireless, distributed configuration. The system may include a remote subsystem and an integrated subsystem. The remote subsystem, including the PCP block and optionally an ASRC block, may be implemented remotely from the consumer electronic device (e.g. in the cloud, on a local server, on a network computer, on a router, etc.). The integrated subsystem, including the DD block and optionally an ASRC block, may be integrated into the consumer electronic device. The remote and integrated subsystems may be configured to communicate wirelessly or via a network streaming protocol in order to transfer one or more enhanced audio signals from the PCP block to the DD block. Such an implementation may be advantageous for off-loading processing functions from the consumer electronic device (e.g. to save on power consumption). Such an implementation may be advantageous for streaming audio from an online or remote streaming service. The ASRC block may be configured with multiple operating states, such as a low power state, a high audio performance state, etc. The ASRC block may be configured to accept a control signal suitable for placing the ASRC block into an alternative state.

According to yet another aspect there is provided, a method for enhancing audio performance of a consumer electronic device. The method includes determining a set of parameters for a configurable audio processing system, optimizing the audio processing system with the parameters, and integrating the optimized audio processing system into the consumer electronic device.

The parameters may be optimized by analyzing the consumer electronic device in a test chamber (e.g. an anechoic test chamber) including one or more audio sensors, and running a configuration algorithm to pre-configure and determine the optimal parameters for the configurable audio processing system in combination with the analysis. The parameters may be iteratively optimized through repetition of the analysis process.

The method may include hardcoding the optimized audio processing system into a hardware descriptive language (HDL) implementation. An HDL implementation may be advantageous for simplifying integration of the audio processing and enhancement system into existing processors and/or hardware on the consumer electronic device. An HDL implementation may also be advantageous for encrypting and protecting the parameters in the audio processing system.

The method may include optimizing the HDL implementation for reduced power, reduced footprint or for integration into a particular semiconductor manufacturing process (e.g. 13 nm-0.5 μm CMOS, CMOS-Opto, HV-CMOS, SiGe BiCMOS, etc.). This may be advantageous for providing an enhanced audio experience for a consumer electronic device without significantly impacting power consumption or adding significant hardware or cost to an already constrained device.

According to another aspect there is provided, a method for enhancing audio in a consumer electronic device. The method includes integrating a configurable audio enhancement system into a consumer electronic device, testing the consumer electronic device during the manufacturing, validation or final testing process, and updating the audio enhancement system within the consumer electronic device.

In aspects, the consumer electronic device may be tested in an automated test cell. The automated test cell may run a diagnostic test on the consumer electronic device and record audio output from the device obtained during the diagnostic test. An update to the audio enhancement system may be generated using data obtained from the diagnostic test, and the automated test cell may update the audio enhancement system on the consumer electronic device.

### BRIEF DESCRIPTION OF THE DRAWINGS

Several aspects of the disclosure can be better understood with reference to the following drawings. In the drawings, like reference numerals designate corresponding parts throughout the several views.

FIGS. 1 a-f—Show schematics of an audio enhancement system (AES) in accordance with the present disclosure.

FIG. 2—Shows a schematic of a parametrically configurable processing (PCP) block in accordance with the present disclosure.

FIG. 3—Shows a schematic of a digital driver (DD) block in accordance with the present disclosure.

FIG. 4—Shows a schematic of an asynchronous sample rate converter (ASRC) block in accordance with the present disclosure.

FIGS. 5a-c—Show a consumer electronic device with integrated audio enhancement system and audio performance therefrom with and without the audio enhancement system.

FIGS. 6a and 6b—show methods for enhancing the audio performance of a consumer electronic device in accordance with the present disclosure.

FIG. 7—shows a method for enhancing the audio performance of a consumer electronic device in accordance with the present disclosure.

### DETAILED DESCRIPTION

Particular embodiments of the present disclosure are described hereinbelow with reference to the accompanying drawings; however, the disclosed embodiments are merely examples of the disclosure and may be embodied in various forms. Well-known functions or constructions are not described in detail to avoid obscuring the present disclosure in unnecessary detail. Therefore, specific structural and functional details disclosed herein are not to be interpreted as limiting, but merely as a basis for the claims and as a representative basis for teaching one skilled in the art to variously employ the present disclosure in virtually any appropriately detailed structure. Like reference numerals may refer to similar or identical elements throughout the description of the figures.

By consumer electronic device is meant a cellular phone (e.g. a smartphone), a tablet computer, a laptop computer, a portable media player, a television, a portable gaming device, a gaming console, a gaming controller, a remote control, an appliance (e.g. a toaster, a refrigerator, a bread maker, a microwave, a vacuum cleaner, etc.) a power tool (a drill, a blender, etc.), a robot (e.g. an autonomous cleaning robot, a care giving robot, etc.), a toy (e.g. a doll, a figurine, a construction set, a tractor, etc.), a greeting card, a home entertainment system, etc. All consumer electronic devices have an inherent acoustic signature as described below. The audio enhancement system may be configured to compensate for this acoustic signature to enhance and/or standardize the audio output from the device. In the case of the consumer electronic device being an appliance or a power tool, the audio enhancement system may be configured to cancel operating noise, augment operating noise, provide alerts to a user, etc. The audio enhancement system may be configured as an all-digital implementation, which may be suitable for lowering system cost, specifically in terms of the processor, but also in terms of using lower cost transducers, reducing power requirements, etc. The audio enhancement system may also be configured to maintain acceptable audio performance in a low cost application when paired with an exceedingly low cost transducer. In the case of a mobile or battery operated consumer electronic device, such as a portable gaming device, the audio enhancement system may be configured to enhance the audio experience for the user while minimizing power usage, thus extending the battery life, reducing onboard heat generation, etc.

By transducer 3, 9 is meant a component or device such as a loudspeaker suitable for producing sound. A transducer 3, 9 can be based on one of many different technologies such as electromagnetic, thermoacoustic, electrostatic, magnetostrictive, ribbon, audio arrays, electroactive materials, and the like. Transducers 3, 9 based on different technologies may require alternative driver characteristics, matching or filtering circuits but such aspects are not meant to alter the scope of this disclosure.

By transducer module 5 is meant a subsystem including both a transducer 9 and a circuit 7. The circuit 7 provides additional functionality (e.g. power amplification, energy conversion, filtering, energy storage, etc.) to enable a driver external to the transducer module 5 to drive the transducer 9. Some non-limiting examples of the circuit 7 (e.g. a passive filter circuit, an amplifier, a de-multiplexer, a switch array, a serial communication circuit, a parallel communication circuit, a FIFO communication circuit, a charge accumulator circuit, etc.) are highlighted throughout the disclosure.

By input audio signal 1 is meant one or more signals (e.g. a digital signal, one or more analog signals, a 5.1 surround sound signal, an audio playback stream, etc.) provided by an external audio source (e.g. a processor, an audio streaming device, an audio feedback device, a wireless transceiver, an ADC, an audio decoder circuit, a DSP, etc.).

By acoustic signature is meant the audible or measurable sound characteristics of a consumer electronic device dictated by its design that influence the sound generated by the consumer electronic device. The acoustic signature is influenced by many factors including the loudspeaker design (speaker size, internal speaker elements, material selection, placement, mounting, covers, etc.), device form factor, internal component placement, screen real-estate and material makeup, case material selection, hardware layout, and assembly considerations amongst others. Cost reduction, form factor constraints, visual appeal and many other competing factors are favored during the design process at the expense of the audio quality of the consumer electronic device. Thus the acoustic signature of the device may deviate significantly from an ideal response. In addition, manufacturing variations in the above factors may significantly influence the acoustic signature of each device, causing further part to part variations that degrade the audio experience for a user. Some non-limiting examples of factors that may affect the acoustic signature of a consumer electronic device include: insufficient speaker size, which may limit movement of air necessary to re-create low frequencies, insufficient space for the acoustic enclosure behind the membrane which may lead to a higher natural roll-off frequency in the low end of the audio spectrum, insufficient amplifier power available, an indirect audio path between membrane and listener due to speaker placement often being on the back of a TV or under a laptop, relying on reflection to reach the listener, among others factors.

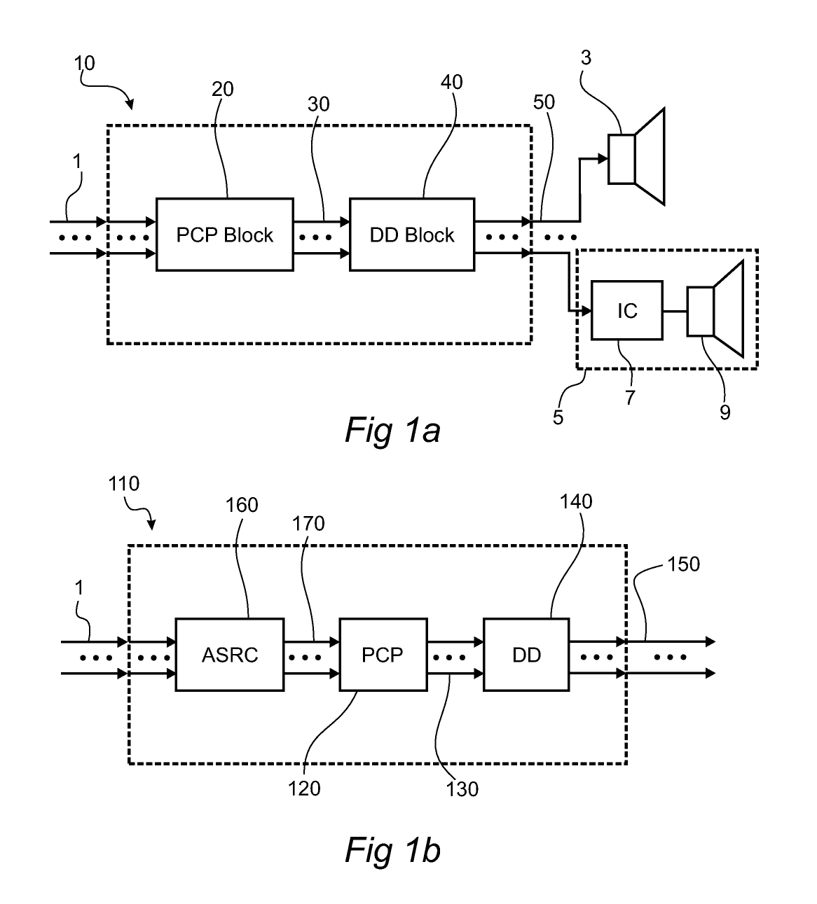

FIGS. 1a-f show non-limiting examples of schematics of an audio enhancement system 10, 110, 110′, 210, 310, 410 for a consumer electronic device in accordance with the present disclosure. The audio enhancement system 10, 110, 110′, 210, 310, 410 accepts a one or more input audio signals 1 from a source (e.g. a processor, an audio streaming device, an audio feedback device, a wireless transceiver, an ADC, an audio decoder circuit, a DSP, etc.), and provides one or more output signals 50, 150, 250, 350, 450 to one or more transducers 3, or transducer modules 5. The audio enhancement system 10, 110, 110′, 210, 310, 410 includes blocks (e.g. PCP block, DD block, ASRC block, etc.) which transform the input audio signal 1 to produce the output signal 50, 150, 250, 350, 450.

The audio enhancement system 10, 110, 110′, 210, 310, 410 may be embedded in an application specific integrated circuit (ASIC) or be provided as a hardware descriptive language block (e.g. VHDL, Verilog, etc.) for integration into a system on chip integrated circuit (ASIC), a field programmable gate array (FPGA), or a digital signal processor (DSP) integrated circuit. One or more blocks (e.g. PCP block, ASRC block, etc.) may also be implemented in software on the consumer electronic device and/or in an associated network (e.g. a local network server, in the cloud, etc.). The system 10, 110, 110′, 210, 310, 410 may be an all-digital hardware implementation. An all-digital implementation may be advantageous to reduce the hardware footprint, reduce power consumption, reduce production costs, and increase the number of integrated circuit processes into which the system may be implemented. The implementation may be integrated into a consumer electronic device in order to provide a complete audio enhancement solution.

FIG. 1a shows a schematic of an audio enhancement system 10 for a consumer electronic device including a parametrically configurable processing (PCP) block 20 and a digital driver (DD) block 40. The audio enhancement system 10 may be configured to accept one or more audio input signals 1 from an audio source. In the schematic shown, the PCP block 20 may be configured to accept the input signal 1 and to produce an enhanced signal 30. The enhanced signal 30 may be provided to the DD block 40 which is configured to convert it into one or more output signals 50, suitable for driving a transducer 3 or a transducer module 5.

FIG. 1b shows a schematic of an audio enhancement system 110 for a consumer electronic device including an asynchronous sample rate conversion (ASRC) block 160, a PCP block 120 and a DD block 140. The system 110 is configured to accept one or more audio input signals 1 from an audio source. In the schematic shown, the ASRC block 160 may be configured to accept the input signal 1 and to produce a converted signal 170. The converted signal 170 is provided to the PCP block 120, which in turn is configured to transform it into an enhanced signal 130. The enhanced signal 130 is provided to the DD block 140, which may be configured to produce an output signal 150 from the enhanced signal 130. Placement of an ASRC block 160 between the input to the system 110 and the PCP block 120 may be advantageous for use in memory constrained devices. In this case, an ASRC block 160 may allow for the use of a single set of parameters that are irrespective of the sampling rate of the input audio signal 1, for the rest of the processing. An ASRC block 160 placed at the input to the system 110 may also remove jitter from the input audio signal 1, which may be advantageous for enhancing the sound from some types of input sources.

FIG. 1c shows a schematic of an audio enhancement system 110′ for a consumer electronic device including a PCP block 120′, an ASRC block 160′, and a DD block 140′. The system 110′ is configured to accept one or more audio input signals 1 from an audio source. The PCP block 120′ is configured to accept the input signal 1 and produce an enhanced audio signal 130′, which is delivered to the ASRC block 160′. The ASRC block 160′ may be configured to accept the enhanced audio signal 130′ and to produce a converted enhanced audio signal 170′, which is delivered to the DD block 140′. The DD block 140′ may be configured to produce one or more output signals 150′ to drive one or more transducers or transducer modules (not explicitly shown).

FIG. 1d shows a schematic of an audio enhancement system 210 for use in a consumer electronic device, including remote subsystem 212 and an integrated subsystem 214. The system 210 accepts one or more audio input signals 1 from an audio source. As shown, the remote subsystem 212 includes a PCP block 220 and optionally includes an ASRC block 260. The remote subsystem 212 accepts the input signal 1 into the ASRC block 206, which produces a converted signal 270, which is delivered to the PCP block 220. The PCP block 220 produces an enhanced audio signal 230 which is transmitted to the integrated subsystem 214. As shown in FIG. 1d, the enhanced audio signal 230 may be wirelessly transmitted 290 to the integrated subsystem 214. The enhanced audio signal 230 may be transformed during the transmission process, thus a modified enhanced audio signal 230′ may be provided to the integrated subsystem 214. The integrated subsystem 214 may be configured to accept the enhanced audio signal 230′ to an included DD block 240. The DD block 240 produces an output signal 250 suitable for driving one or more transducers or transducer modules (not explicitly shown).

The remote subsystem 212 may be implemented remotely from the consumer electronic device (e.g. in the cloud, on a local server, on a network computer, on a router, etc.). This may be advantageous for offloading computation requirements of the remote subsystem 212 from the limited resources of the consumer electronic device. This may also be advantageous for simplifying or customizing a user experience with an audio streaming process (e.g. a cloud based audio streaming service). In one example, a user profile stored with an audio streaming service may include parameters for the remote subsystem 212 suitable for optimizing audio output on the intended consumer electronic device. Thus an audio stream 1 from the audio streaming service may be remotely processed in a remote subsystem 212 before sending the enhanced audio stream 230 to the integrated module 214 on the consumer electronic device for playback.

The ASRC block may be configured with multiple operating states, such as a low power state, a high audio performance state, etc. The ASRC block may be configured to accept a control signal (e.g. a “battery low” signal, a “volume” signal, etc.) from the consumer electronic device suitable for placing the ASRC block into an alternative state.

The integrated subsystem 214 may be integrated into hardware or software aspects of the consumer electronic device. As shown in FIG. 1d, the integrated subsystem 214 may include a DD block 240. The integrated subsystem 214 may also include an ASRC block, PCP block, etc. to further enhance the audio experience for the user while effectively offloading the majority of the computational effort of enhancing an audio stream 1 to the remote subsystem 212.

FIG. 1e shows a schematic of an audio enhancement system 310 for use in a consumer electronic device. The system 310 includes or accepts one or more parameters 372, 374, 376 by which the internal blocks 360, 320, 340 or the system 310 may be configured for use on a specific consumer electronic device. The system 310 is configured to accept one or more audio signals 1 from an audio source (not explicitly shown). As shown in FIG. 1e, the audio enhancement system 310 includes an ASRC block 360, which is configured to accept the audio input signal 1 and to produce a converted signal 370. The converted signal 370 is provided to a PCP block 330, which is configured to produce an enhanced audio signal 330. The enhanced signal 330 is delivered to the DD block 340, which produces one or more output signals 350 for driving one or more transducers or transducer modules (not explicitly shown). The parameters may be integrated into any block 320, 340, 360, in the system 310 (e.g. parameters 372 are shown integrated into the ASRC block 360). The parameters may also be integrated into the system in general 310, for use by any block 320, 340, 360 within the system 310 (e.g. parameters 374 are shown integrated into the system 310 for use by the PCP block 320). The parameters may be located externally to the system 310, and the system 310 may be configured to accept one or more external parameters 376 for use by any block 320, 340, 360 within the system 310 (e.g. the external parameters 376 are accepted into the system 310 for use by the DD block 340).

The parameters 372, 374, 376 may be pre-configured during the design, validation, or testing process of the consumer electronic device. Alternatively, additionally, or in combination, the parameters 372, 374, 376 may be pre-configured, tweaked or optimized during the manufacturing, quality control, and/or testing processes of the consumer electronic device. Alternatively, additionally, or in combination, the parameters 372, 374, 376 may be uploaded to the consumer electronic device during a firmware upgrade or through a software update process.

The parameters 372, 374, 376 may be dependent on the particular design of the consumer electronic device into which the system may be integrated and/or to which the system may be interfaced. The parameters 372, 374, 376 may be dependent on the quality of audio drivers, component layout, loudspeakers, material and assembly considerations, housing design, etc. for a specific consumer electronic device, brand of device, or product family of devices (e.g. a laptop product family, a mobile phone series). The parameters 372, 374, 376 may also depend implicitly on other design factors such as cost, visual appeal, form factor, screen real-estate, case material selection, hardware layout, signal types, communication standards, and assembly considerations amongst others of the consumer electronic device.

The parameters 372, 374, 376 may be incorporated into the audio enhancement system 10, 110, 110′, 210, 310, 410 to create an enhanced audio experience on the associated consumer electronic device. Alternatively, the parameters 372, 374, 376 may be used to optimize the system 10, 110, 110′, 210, 310, 410, essentially being intimately integrated into the system 10, 110, 110′, 210, 310, 410 architecture to provide the enhanced audio experience.

FIG. 1f shows an audio enhancement system 410 for use in a consumer electronic device. The audio enhancement system 410 may be configured to accept one or more audio input signals 1 from an audio source (not explicitly shown) and delivers one or more output signals 450 to one or more transducers or transducer modules (not explicitly shown). The audio enhancement system 410 may accept one or more control signals 420 which may be used by any block within the system 410. The system 410 may be configured to provide one or more feedback signals 430 to an external recipient (e.g. the audio source, an external processor, a network, etc.). The system 410 may also include a bi-directional serial communication pipe 440. The system 410 may include a communication block (not explicitly shown) for decoding and managing the communication pipe 440. The communication pipe 440 may be configured to provide a channel for communicating control signals and/or feedback signals between the system 410 and an external entity (e.g. the audio source, an external processor, a network, etc.).

The system 410 may include one or more ASRC blocks, PCP blocks, DD blocks, etc. The system 410 or any block therein may be configured to accept one or more control signals 420 from the audio signal source, a supervisor, a processor, etc. The system 410 may be configured to respond to the control signal to reduce power consumption, enter a low-power state, run a diagnostic test, or the like. The control signals 420 may provide a service (e.g. a clock source, a timer, a flag, a control bit, etc.) to one or more of the blocks in the system 410.

One or more of the blocks in the system 410 may be adjustable between states of efficient audio processing and high audio quality. The degree of adjustment between states may be set by the control signal 420.

The system 410 may include a feedback block (not explicitly shown) configured to provide a feedback signal 430. Alternatively, additionally, or in combination, any block within the system 410 may be configured to provide one or more feedback signals 430. The feedback signals 430 may be provided to the audio signal source, a supervisor, a processor, a network, etc. The feedback signal 430 may be a quantitative metric related to membrane movement or location, speaker drive current, an electrical characteristic (e.g. speaker drive voltage, a near DC impedance, an impedance spectrum, portion thereof, etc.), system power supply, speaker temperature, processing efficiency of the audio signal(s) 1, status of a block or the system 410, power consumption of one or more blocks within or of the system 410, changes in the transducer 3, 9 characteristics (e.g. voice coil resistance, input impedance, impedance spectrum, displacement parameter, etc.). The feedback signal 430 may include information suitable for tweaking and/or optimizing one or more of the parameters 372, 374, 376.

In aspects, a PCP-block in accordance with the present disclosure may include a non-linear feedback control system including an observer and the audio system may include a means for producing one or more feedback signals 430. The observer may be configured to accept one or more of the feedback signals 430 or signals generated therefrom and to generate one or more of the estimated states from one or more of the feedback signals 430 and one or more of the control signals. In aspects, the observer may include a nonlinear observer, a sliding mode observer, a Kalman filter, an adaptive filter, a least means square adaptive filter, an augmented recursive least square filter, an extended Kalman filter, ensemble Kalman filter, high order extended Kalman filters, a dynamic Bayesian network. In one non-limiting example, the observer may include an unscented Kalman filter or an augmented unscented Kalman filter to generate one or more of the estimated states.

In aspects, an audio enhancement system in accordance with the present disclosure may include a protection block, the protection block configured to analyze one or more of the input signals, feedback signals 430, the estimated states and/or the control signals and to modify the control signals based upon the analysis so as to limit the temperature and/or the voice coil excursion of an associated transducer 3, 9. In aspects, the audio enhancement system may accept a voltage and/or current from the transducer 3, 9 as input into the observer.

In one non-limiting example, a DD block within the system 410 may include a transducer diagnostic circuit for analyzing the impedance of an attached transducer to the device. The system 410 may also include and/or communicate with an audio sensor (e.g. a microphone) to register audio output from the transducer during a diagnostic test, via an inline modification during production, etc. Upon receipt of a control signal 420 or at predetermined intervals, the DD block may perform a diagnostic test on the transducer using the diagnostic circuit. The diagnostic circuit may provide one or more feedback signals 430 characterizing diagnostic data, diagnostic outcomes, etc. from the test to an external entity (e.g. an audio source, a processor, a supervisor, a network, etc.). The resulting feedback signal 430 may be further analyzed and/or compared with prior diagnostic test results to determine the state of the transducer 3, 9. If significant changes in the properties of the transducer are detected, the parameters 372, 374, 376 may be updated based on the diagnostic test results, previous diagnostic test results, audio output of the transducer during the diagnostic test, and the like. Updated parameters 372, 374, 376 may be uploaded to the system 410 if they vary significantly from those already in the system 410.

To communicate control signals 420, and/or feedback signals 430, the system 410 may further include one or more communication pipes 440. The communication pipe 440 may be an analog protocol, I²S, RS-232, RS-422, microwire, 1-wire, bit banging, RS-423, RS-485, I²C, SPI, UART, firewire, Ethernet, MIDI, serial ATA, CAN, MOST bus architecture, or the like.

The PCP block 20, 120, 220, 320 may include one or more transfer functions that relate the incoming signals to the PCP block 20, 120, 220, 320 to the enhanced audio signal 30, 130, 130′, 230, 330 produced by the PCP block 20, 120, 220, 320. The PCP block 30, 130, 130′, 230, 330 may include and/or may be configured to accept one or more parameters 372, 374, 376 that influence at least a portion of the transfer function between one or more incoming signals to one or more enhanced signals 30, 130, 130′, 230, 330. The PCP block 30, 130, 130′, 230, 330 may include a memory element for storage of one or more of the parameters 372, 374, 376. Alternatively, additionally, or in combination, one or more parameters 374, 376 may be provided in a separately located memory element, loaded into the PCP block 30, 130, 130′, 230, 330 during power-up, or hardware encoded directly into a VHDL implementation of the system. The parameters 372, 374, 376 may be loaded from a network (e.g. over the internet, from the cloud, etc.).

The PCP block 30, 130, 130′, 230, 330 may be configured to provide such functions as FIR filtering, IIR filtering, warped FIR filtering, transducer artifact removal, disturbance rejection, user specific acoustic enhancements, headphone sound externalization, user safety functions, emotive algorithms, psychoacoustic enhancement, signal shaping, single or multi-band compression, expanders or limiters, watermark superposition, spectral contrast enhancement, spectral widening, frequency masking, quantization noise removal, power supply rejection, crossovers, equalization, amplification, driver range extenders, power optimization, linear or non-linear feedback or feed-forward control systems, and the like. The PCP block 30, 130, 130′, 230, 330 may include one or more of the above functions, either independently or in combination. One or more of the included functions may be configured to depend on one or more of the parameters 372, 374, 376.

The PCP block 30, 130, 130′, 230, 330 may be configured to provide echo cancellation, environmental artifact correction, reverb reduction, beam forming, auto calibration, stereo widening, virtual surround sound, virtual center speaker, virtual sub-woofer (by digital bass enhancement techniques), virtual surround sound from headphones, noise suppression, sound effects, or the like. One or more of the included functions may be configured to depend on one or more of the parameters 372, 374, 376.

The PCP block 30, 130, 130′, 230, 330 may be configured to impose ambient sound effects onto an audio signal 1, such as by transforming the audio input signal 1 with an ambient environmental characteristic (e.g. adjusting reverb, echo, etc.) and/or superimposing ambient sound effects onto the audio input signal 1 akin to an environmental setting (e.g. a live event, an outdoor setting, a concert hall, a church, a club, a jungle, a shopping mall, a conference setting, an elevator, a conflict zone, an airplane cockpit, a department store radio network, etc.).

Additionally, alternatively, or in combination, the PCP block 30, 130, 130′, 230, 330 may be configured to accept and respond to a location based control signal 420 from the audio signal source, a processor, or a network (e.g. the internet, the cloud, a LAN, etc.). The PCP block 30, 130, 130′, 230, 330 may alter the ambient sound effects based on the location-based control signal 420. The system 10, 110, 110′, 210, 310, 410 may include a memory element suitable for storing the ambient sound effects. The system 10, 110, 110′, 210, 310, 410 may be configured to receive ambient sound effects from the audio signal source, a processor, a network, or the like.

The ambient sound effects may include specific information about a user, such as name, preferences, etc. The ambient sound effects may be used to securely superimpose personalized information (e.g. greetings, product specific information, directions, watermarks, handshakes, etc.) into an audio stream.

An audio enhancing system 10, 110, 110′, 210, 310, 410 in accordance with the present disclosure, including a PCP block 20, 120, 220, 320 may be used in a consumer electronic device, the consumer electronic device or the system 10, 110, 110′, 210, 310, 410 having a limited number of loudspeakers 3, 9 (e.g. 1 or 2). The system 10, 110, 110′, 210, 310, 410 may be configured to accept a 5.1 surround sound signal 1 and to deliver it to the PCP block 20, 120, 120′, 220, 320. The PCP block 20, 120, 120′, 220, 320 includes preconfigured functions for creating a virtual center speaker and a virtual sub-woofer from the 5.1 surround sound signal, or the like, and adding them to the 5.1 surround sound signal 1 to form an enhanced audio signal 30, 130, 130′, 230, 330. The PCP block 20, 120, 120′, 220, 320 may include one or more virtual sound processing functions to further reduce the number of necessary loudspeakers to 2. The PCP block 20, 120, 120′, 220, 320 may be configured to deliver the enhanced audio signal 30, 130, 130′, 230, 330 to a DD block 40, 140, 240, 340 which is configured generate an output signal 50, 150, 250, 350, 450 suitable for driving the limited number of loudspeakers. This implementation may be advantageous to improve audio quality in low cost and highly constrained consumer electronic devices.

An arbitrary or asynchronous sample rate converter (ASRC) block 160, 260, 360 may be integrated into the system 110, 110′, 210, 310, 410 between the input and the PCP block 120 (e.g. as shown in FIG. 1b), between the PCP block 120 and the DD block 140 (e.g. as shown in FIG. 1c), or integrated into either the PCP block 20, 120, 120′, 220, 320 or the DD block 40, 140, 240, 340. The ASRC block 160, 260, 360 may be configured to accept one or more audio signals (e.g. a digital audio signal) of arbitrary sample rate from an audio signal source (e.g. a processor, an audio streaming device, an audio feedback device, a wireless transceiver, an ADC, an audio decoder circuit, the PCP block 120, etc.), and to produce one or more converted signals 170, 170′, 270, 370 with a different sample rate. Depending on the particular implementation, the ASRC block 160, 260, 360 may be configured to deliver one or more converted signals 170, 170′, 270, 370 to the PCP block 120, 220, 320 (e.g. as shown in FIGS. 1b, 1d and 1e), the DD block 140 (e.g. as shown in FIG. 1c) or to elements within either block 120, 220, 320, 140. An ASRC block 160 placed at the input to the system 110 may be configured to remove jitter from the input audio signal 1, which may be advantageous for enhancing the sound from some types of input sources.

The DD block 40, 140, 240, 340 may include a pulse width modulator (PWM) and/or a signal conversion subsystem. The DD block 40, 140, 240, 340 may be pre-configured and/or pre-selected to drive a range of electroacoustic transducers (e.g. electromagnetic, thermoacoustic, electrostatic, magnetostrictive, ribbon, arrays, electroactive material transducers, etc.). The DD block 40, 140, 240, 340 may be configured to provide a power efficient PWM signal to the transducer 3, 9 or the input of a transducer module 7 (e.g. a passive filter circuit, an amplifier, a de-multiplexer, a switch array, a serial communication circuit, a parallel communication circuit, a FIFO communication circuit, a charge accumulator circuit, etc.).

In aspects, a signal conversion subsystem in accordance with the present disclosure may be configured to convert an input signal to a pulse width modulated (PWM) output signal may include a clock source for generating and/or means for accepting a clock signal; a carrier generator configured to generate a carrier signal with a carrier signal frequency; a cross-point section (CPS) block including a CPS comparator to compare the carrier signal to the input signal or a signal derived therefrom to produce a triggered signal based on the comparison and the input signal or the signal derived therefrom; a noise shaper configured to bit depth reduce the triggered signal to form a truncated signal; and a PWM comparator configured to compare the truncated signal and/or a signal generated therefrom with the carrier signal to produce the PWM output signal.

In aspects, the signal conversion subsystem may include a sample rate converter to resample the input signal to a resampled signal with a sample rate greater than the carrier signal frequency, the CPS comparator configured to accept the resampled signal.

In aspects, the sample rate converter may include a counter configured to generate a count-disparity signal from the clock signal and the input signal; a first sigma delta unit configured to calculate a temporal correction value from the count disparity signal; a resampled clock generator configured to generate one or more resampled clock signals from the temporal correction value; and/or a second sigma delta unit configured to generate the resampled signal from one or more of the resampled clock signals and the input signal.

In aspects, the noise shaper may be configured to shift the noise on the triggered signal, the input signal, and/or the resampled signal to a substantially inaudible frequency band to form the truncated signal. The noise shaper may include an n^{th} order delta-sigma modulator configured to perform the bit depth reduction and/or noise shifting wherein n is a positive integer. The noise shaper may include a threshold of hearing model.

In aspects, the carrier generator may include or be configured to accept a phase correction parameter, the carrier signal dependent upon the phase correction parameter. The phase correction parameter may be configured to set an initial value for the carrier signal.

In aspects, the signal conversion subsystem may include an analyzer configured to accept the input signal, the resampled signal or a signal generated therefrom and/or an external input and to calculate a PWM control signal, the carrier generator, the PWM comparator, and/or the noise shaper configured to accept the PWM control signal. The analyzer may be configured to calculate a power level from at least a portion of the resampled signal or a signal generated therefrom, the PWM control signal dependent upon the power level. The analyzer may be configured to accept an external input at least partially representative of a property selected from a group including temperature, humidity, sound level, loudspeaker feedback (e.g. voice coil temperature, impedance, excursion, etc.), voltage level, transducer current level, speaker enclosure temperature, speaker enclosure pressure level, and/or a combination thereof.

In aspects, the signal conversion subsystem may include a FIFO buffer coupled to the counter and the input signal, configured to store successive samples of the input signal and the count-disparity signal and/or an averaging block, coupled to the counter or the FIFO buffer and the first sigma delta loop, configured to calculate an averaged count-disparity signal from the count disparity signal, the first sigma delta loop configured to accept the averaged count-disparity signal.

In aspects, the signal conversion subsystem may include a low pass filter coupled to the resampled clock generator and the second sigma delta loop, the low pass filter configured to accept one or more resampled clock signals and the input signal or the de-jittered signal, and to calculate a filtered intermediate signal, the second sigma delta loop configured to accept the filtered intermediate signal. The low pass filter may be a low pass polyphase FIR filter.

Some non-limiting examples of waveforms for the carrier signal include a sawtooth, a zigzag, and a sinusoid.

In aspects, the sample rate converter may be configured to resample the input to a sample rate in sync with the clock signal or a signal derived therefrom.

In aspects, the CPS block may include a data ready function configured to update the triggered signal in sync with the carrier signal (e.g. such as when the carrier signal is at a maximum or a minimum value, etc.).

The PCP block 20, 120, 120′, 220, 320 may include a power optimization function, dependent on one or more of the parameters 372, 374, 376. The power optimization function may be configured via one or more of the parameters 372, 374, 376 to optimize power transfer from the DD block 40, 140, 240, 340 to the transducer 3, 9.

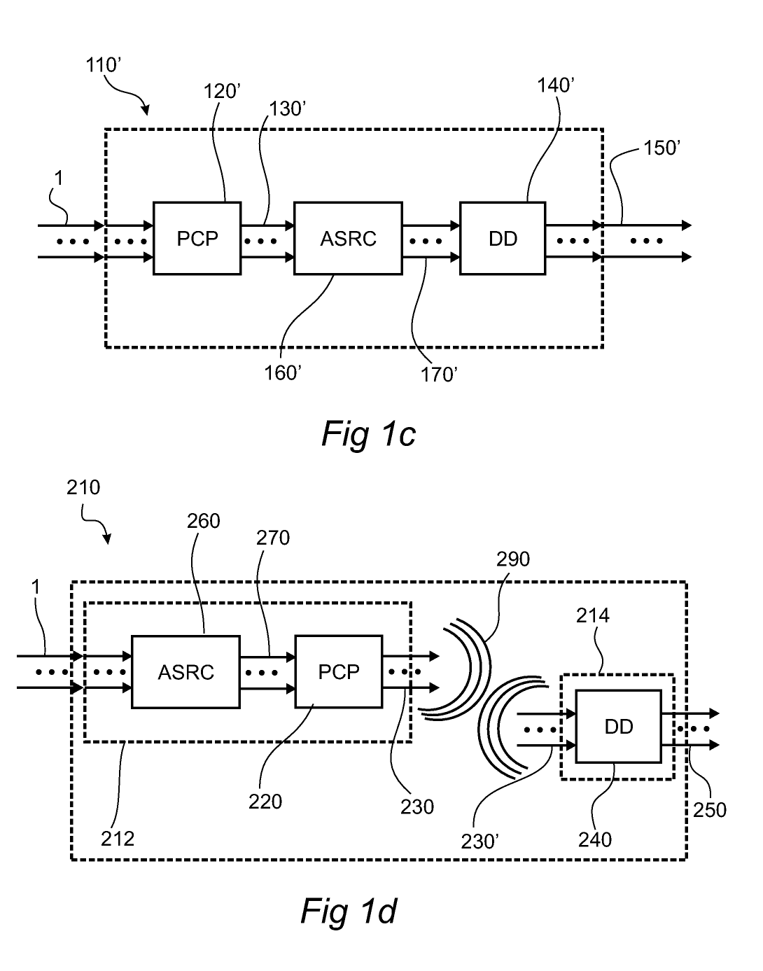

FIG. 2 shows a non-limiting example of a parametrically configured processing (PCP) block 520 including a finite impulse response (FIR) function 522, a psychoacoustic function 524 and a limiting function 534. In aspects, the PCP block 520 may include one or more parameters 572, 574, 576 such as integrated into a function 522 (e.g. the parameters 572 integrated into the FIR function 522), as integrated into the PCP block 520 for use by a function 524 (e.g. the parameters 574), and provided externally to the PCP block 520 for use by one or more functions 534 within the PCP block 520 (e.g. the parameters 576). The PCP block 520 is configured to accept an input signal 501 which may be provided from another block in an audio enhancement system or from an external audio source. The input signal 510 is provided to the FIR function 522, which produces a pre-psych signal 526 and a through signal 524. The pre-psych signal 526 may include spectral content suitable for psychoacoustic modification while the through signal 524 may include spectral content that is not applicable or necessary for psychoacoustic modification. The pre-psych signal 526 is input to the psychoacoustic function 524. The psychoacoustic function 524 outputs a post-psych signal 532 for input to the limiting function 534. The limiting function 534 accepts the post-psych signal 532 and the through signal 524 and produces and enhanced signal 530. The enhanced signal 530 exits the PCP block 522 for delivery to other blocks in the system.

A non-limiting example of a FIR function 522 is shown in the following equation 1:

$$y [ n ] = {\sum }_{i = 0}^{N} {b}_{i} x [ n - i ] \qquad [ equation 1 ]$$

where x[n] is the input signal 501, y[n] is the output signal 526, and bi are the filter coefficients, which may be at least partially derived from the parameters 572. The FIR function 522 is of order N. The order of the function 522 may be determined from the parameters 572 or preconfigured with a practical value. The FIR function 522 may also implement real-bass enhancement onto the input signal 501.

The psychoacoustic function 524 generally improves the perceived bass (e.g. the psycho-acoustic bass (PAB)). The psychoacoustic function 524 may include a harmonic overtone generator (HOG), a delay function, a high pass filter and a low pass filter and one or more amplifiers. The HOG allows for an increase in perceived bass at the expense of distortion. A non-limiting example of a psychoacoustic function 524 may include a high pass filtered and delayed signal path in parallel with a low pass filtered and HOG signal path, both signal paths being summed at the output to form a post-psych signal 532. The at least a portion of the device specific aspects of the HOG and the psychoacoustic function 528 may be determined by the parameters 574.

The limiting function 534 provides boundaries to the amplitude of the enhanced signal 530. The properties of the limiting function 534 may be at least partially configured by the parameters 576. The limiting function 534 ensures that the amplitude of the enhanced signal 530 does not exceed safe operating limits, does not enter into nonlinear transducer extensions, etc. The limiting function 534 may provide an equalizer-function to compensate the enhanced signal 530 for variation in the spectral performance of the transducer 3, 9 and/or transducer module 5.

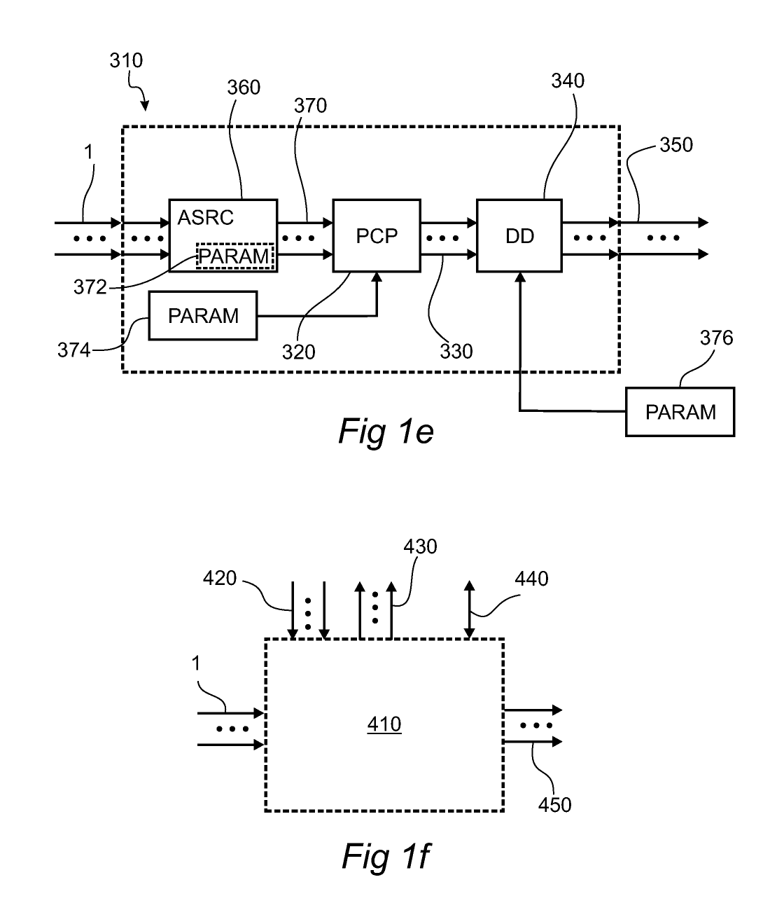

FIG. 3 shows a non-limiting example of a DD block 640 for use in an audio enhancement system 10, 110, 110′, 210, 310, 410. The DD block 640 includes a modulation module 642, a switch module 646 and an optional compensator 648. The input signal 601 is brought to the modulation module 642, which generates one or more binary signals 644. The binary signal 644 is input to the switch module 646, which may be configured to generate an output signal 650 suitable for driving one or more transducers and/or transducer modules (not explicitly shown). The compensator 648 may be configured to interface with the modulation module 642 and the switch module 646 and may be used to adjust the modulated output in exceptionally low or high duty cycle operation of a transducer. The DD block 620 also includes one or more integrated parameters 674 available to the DD block 640 or any function therein, and one or more parameters 672 available to a function within the DD block 640 (e.g. the switch module 646). The parameters 672, 674 may be used to adjust DC offset, remove transducer dependent anomalies, adjust extreme duty cycle performance values for a compensator 648, compensate for pulse width error or quantization errors, configure nonlinear filtering effects (e.g. simulating nonlinear LP effects, distortion adjustment, total harmonic distortion, dead-time effects, etc.), reject power disturbances, adjust for changes in control signals, provide calibration of feedback signals, and the like.

The modulation module 642 may be configured to accept one or more input signals 601 and generates a binary signal 644 to drive a switch module 646. The modulation module 642 may be configured to perform this operation in the digital domain in order to save power and resource requirements. A purely digital implementation of a modulation module 642 may be configured to accept a digital input audio signal 601 and produces one or more binary signals 644. The modulation module 642 may implement a pulse-width, pulse-density, pulse-amplitude, delta-sigma modulation scheme, or the like. In analog embodiments, the binary signal 644 may be generated by comparing a fluctuating signal (e.g. an internally generated sinusoidal signal, saw-tooth signal, etc.) with the incoming values of the input signal 601. Several techniques can be used to perform this function including simple compensation based pulse-width modulation (PWM), pulse density modulation, pulse frequency modulation, sliding mode control, self-oscillating modulation, or discrete-time forms of modulation such as delta-sigma modulation, among others.

In aspects, the compensator 648 may provide various forms of error correction such as quantization distortion correction, noise shaping, expanding the linear mode of operation, compensating for dead-time, etc.

The switch module 646 may include a half-bridge or full-bridge push-pull transistor stage suitable for generating output signals based on voltage, current, charge, etc. to drive a range of transducer technologies.

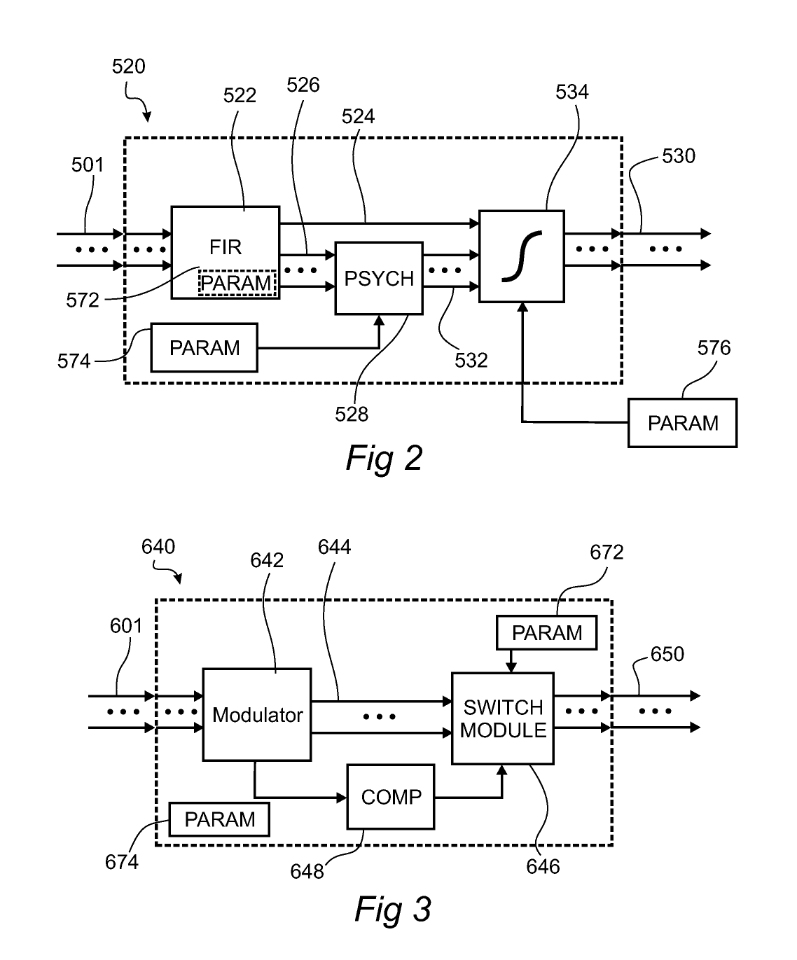

FIG. 4 shows a non-limiting example of an asynchronous sample rate conversion (ASRC) block 760. The ASRC block 760 includes a finite impulse response (FIR) interpolator 766. The FIR interpolator 766 accepts one or more input signals 701 from an external block or entity. The FIR Interpolator 766 may also accept a control signal 703 (e.g. a clock signal). The FIR interpolator 766 may include one or more parameters 776, which may be used for internal compensation, FIR parameter adjustments, non-linear interpolation coefficients, etc. The FIR interpolator 766 produces one or more converted audio signals 770 which may be delivered to other blocks in the audio enhancement system.

In aspects, the ASRC block 760 may be configured to accept a control signal 703 such as a clock signal or generate an internal clock signal, the generated clock signal having a higher sample rate than the sample rate of the input signal 701. The ASRC block 760 may also include a sample rate determination module, for determining the sample rate of the input signal 701. The sample rate determination module may be used to determine the ratio between the sample rate of the input signal 701 and that of the internally generated or provided clock. The higher sample rate clock is generally used for the interpolation function 766 within the ASRC block 760 when forming the converted signal 770.

In aspects, a sample rate converter (ASRC block) in accordance with the present disclosure may be configured to convert an input signal with a first sample rate to a resampled output signal with an output sample rate, and may include a cross enable unit, and a linear interpolation unit. The cross enable unit may be configured to accept the input signal and to produce one or more resampled clock signals and a de-jittered signal. The linear interpolation unit may be configured to accept one or more resampled clock signals and the de-jittered signal, and to produce a resampled output signal at an output sample rate.

In aspects, the cross enable unit may be configured to one or more input signals (e.g. a digital signal, a digital audio stream, a telemetry signal, etc.) from a signal source (e.g. output of an analog to digital converter, a signal processor, an SPDIF converter, an I2S converter, etc.) and to produce one or more resampled clocks and a de-jittered signal. The input signals may have one or more associated first sample rates. The cross enable unit may also be configured to accept and/or generate a clock signal (e.g. a system clock). The cross enable unit may be configured to produce one or more resampled clock signals, generated from one or more of the input signals in combination with the clock signal.

In aspects, the sample rate converter may include a finite impulse response (FIR) filter module in accordance with the present disclosure. The FIR filter module may be placed between the cross enable unit and the linear interpolation unit. The FIR filter module may be configured to produce a filtered intermediate signal from one or more of the resampled clock signals and the de-jittered signal. In aspects, the linear interpolation unit may be configured to accept the filtered intermediate signal instead of the de-jittered signal.

In aspects, the sample rates of the resampled clock signals may be multiples of the averaged input sample rates (e.g. integer multiples, non-integer multiples, rational non-periodic variable multiples, etc.).

In aspects, the resampled clock signals may be used by one or more of the units (e.g. the FIR filter module, the linear interpolation unit, etc.) within the sample rate converter to perform aspects of the sample rate conversion. The resampled clock signals may also be provided as outputs to other systems (e.g. for further signal processing, timing operations, parameter calculation, input signal quality assessment, etc.).

In aspects, the cross enable unit may be configured to produce a de-jittered signal and associated de-jittered clock signal substantially sampled at the mean of the first sample rate. The de-jittered signal may be advantageous in applications where the input signal has a jittery, asynchronous, unreliable, or otherwise variable sample rate, as well as in applications where high performance demands are placed on signal processing aspects of the system.

In aspects, the cross enable unit may include a counter, a FIFO buffer, an averaging block, a first sigma-delta loop and a resampled clock generator. The counter may be configured to count the number of clock cycles on the clock signal between adjacent samples of the input signal to form a count-disparity signal. The FIFO buffer may be configured to store samples of the input signal and/or the count-disparity signal associated with each sample of the input signal for use by other blocks in the cross enable unit. The averaging block may be configured to calculate the moving average of the count-disparity signal to form an averaged count-disparity signal. The first sigma-delta loop may be configured to generate the number of clock cycles that should be inserted between samples at the desired resample rate from the averaged count-disparity signal. The resampled clock generator may be configured to construct one or more resampled clock signals (e.g. one or more intermediate clock signals, a de-jittered clock signal, etc.) from the output of the first sigma-delta loop. In addition or in combination, the de-jittered clock signal may be used as feedback to release corresponding input samples from the FIFO buffer at a de-jittered sample rate.

In one non-limiting example, the resampled clock generator may include a plurality of decimators to generate multiple resampled clock signals (e.g. an integer division of the highest output sample rate, a non-integer division of the highest output sample rate, etc.).

In aspects, the de-jittered clock signal may be fed back into the FIFO buffer, the averaging block, and the first sigma-delta loop so as to synchronize calculations within the cross-enable unit and provide a more stable rate than may be available from the input signal. This approach may be advantageous for improving system performance by substantially removing jitter induced error propagation that may otherwise pass along through a signal processing system, etc.

In aspects, the averaging block may include a moving average filter, a boxcar filter, or the like. The filter may be configured to act so as to remove variability from the count-disparity signal, to produce a stabilized numerical value representing the relationship between the first sample rate and the clock signal.

In aspects, the averaging block may include an averaging function with a non-unity DC gain adjustment to produce a non-unity representation of the count-disparity signal. Such an arrangement may be suitable for forming non-integer resampled rates on one or more of the resampled clock signals. An adjustable gain may also serve as a feedback control signal to other elements of the cross enable unit (e.g. the FIFO buffer). In one non-limiting example, the averaging block may include a moving average filter with an adjustable gain parameter. The FIFO buffer may include a fill value proportional to the fill level of the FIFO buffer. The adjustable gain parameter may be controllably linked to the fill value. Thus the de-jittered sample rate may vary along with the fill level of the FIFO buffer, the relationship between parameters may be established such that the system is self-stabilizing, such that the FIFO buffer fills to a mid-point and remains at the mid-point during operation.

The first sigma-delta loop may include one or more parameters suitable for modifying the count disparity value, or average count disparity value resampled temporal correction value. In one non-limiting example, the first sigma delta loop may include an integer value parameter, such as a power of 2 (e.g. 16). In another non-limiting example, the first sigma-delta loop may include a non-periodic, possibly random number generator (e.g. a pseudorandom Gaussian noise generator). Such a configuration may be advantageous for generating a spread spectrum sampling rate.

In aspects, the cross enable unit may include several of the above elements (e.g. FIFO buffer, sigma-delta loops, averaging blocks, etc.) arranged so as to form a range of multi-rate resampled signals, non-integer resampled signals, etc.

In aspects, the cross enable may further include a decimation unit for down sampling a signal to produce one or more resampled clock signals with a sample rate less than that of the input signal.

In aspects, the cross enable may be adapted to simultaneously manage de-jittering and/or resampled clock signal generation for multiple asynchronous input signals. Such a configuration may be advantageous for sensor fusion applications where a common phase delay must be maintained between several, potentially multi-rate input signals obtained from a range of sensory inputs.

In aspects, the finite impulse response (FIR) filter module may be configured to accept one or more resampled clock signals and the de-jittered signal. The FIR filter module may be configured to produce a filtered intermediate signal at an intermediate sample rate corresponding to one of the resampled clock signals. The FIR filter module may include a FIR filter that samples the de-jittered signal at a rate corresponding to one of the resampled clock signals. The FIR filter may be configured as a low pass filter, a band-pass filter, or the like. In one non-limiting example, the FIR filter may be implemented as a computationally efficient polyphase FIR filter.

In aspects, the FIR filter may be an adaptive and/or reconfigurable filter, the properties of which may be adjusted by an external system, by an adaptation algorithm, a parameter set, or the like. The reconfigurable filter parameters may be stored in the sample rate converter and/or may be updated externally or internally, potentially in real-time.

In aspects, the resampled clock signal generator may be configured to accept reconfigurable parameters from an external source. Alternatively, in combination, or in addition, the resampled clock generator may include a non-periodic rate converting element (e.g. a pseudo random number generator, etc.). The non-periodic rate converting element may be used to create a spread spectrum sample rate, or the like. Such aspects may be advantageous for decreasing the peak electromagnetic radiation operably emitted from the sampling system, etc.

In aspects, the FIR filter may be implemented in a hardware descriptive language (HDL) to provide a structure with implicitly variable precision. A HDL implementation may be advantageous for simple inclusion of the sample rate converter into a signal processing application specific integrated circuit (ASIC), a digital signal processor (DSP), a field programmable gate array (FPGA), or the like.

In one non-limiting example, the FIR filter may include aspects of an inverse system model along with a low-pass function useful for removing aliasing artifacts from an up-sampled input signal. Such a FIR filter configuration may be advantageous for implementing a compensatory function with substantially minimized phase delay, improved computational efficiency, etc.

In aspects, the linear interpolation unit may be configured to accept one or more resampled clock signals and the de-jittered signal or the filtered intermediate signal. The linear interpolation unit may be configured to produce a resampled output signal at an output sample rate. The linear interpolation unit may include a filter element to remove aliasing artifacts from the signal after resampling to the output sample rate.

In one non-limiting example, the linear interpolation unit may include a second sigma delta loop configured to generate successive output samples from associated and/or adjacent samples of the filtered intermediate signal. The sigma delta loop calculates a correction signal dependent on the sample rates of the resampled clock signals and filtered intermediate signal. In general, the correction signal includes an integer part and a remainder part. Upon each cycle at the output sample rate, the integer part of the correction signal is added to the previous resampled output signal sample to form the current resampled output signal sample, while the remainder part is added back into the correction signal to maintain integrity of the conversion process over time.

The corresponding resampled output signal with an associated output sample rate may then be outputted from the sample rate converter for use elsewhere in a signal processing system, transfer to a PWM module, a transducer driver circuit, or the like.

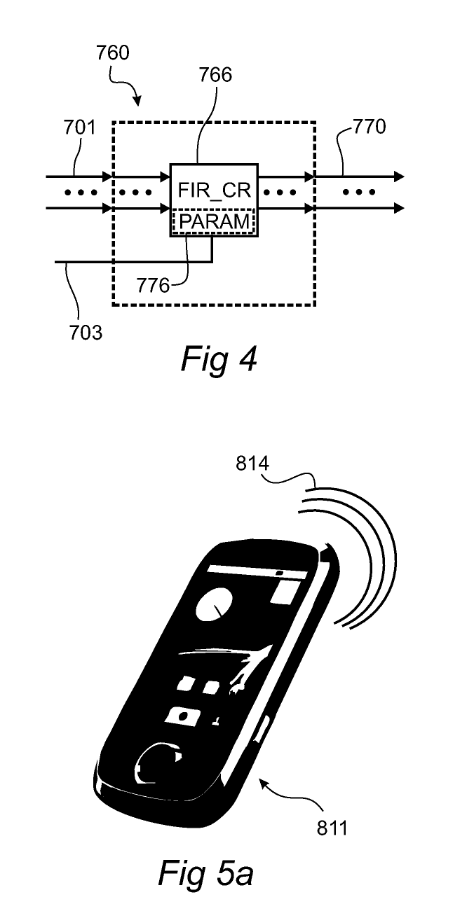

FIG. 5a shows a consumer electronic device 811 (e.g. a smartphone) with an integrated audio enhancement system 10, 110, 110′, 210, 310, 410. The consumer electronic device 881 is shown during operation, producing an audio output 814. The consumer electronic device 881 may be tested to determine its acoustic signature during the design process, the manufacturing process, the validation process, or the like.

FIG. 5b shows a comparison between a frequency response test of the audio output 814 of the consumer electronic device 811 with and without an integrated audio enhancement system 10, 110, 110′, 210, 310, 410. The figure shows a log-linear frequency response plot with frequency along the horizontal axis and amplitude of the audio output 814 along the vertical axis, in units of decibels. The curve 821 represents the frequency response of the consumer electronic device 811 without enhancement. The enhanced audio spectrum 822 shows the frequency response of the consumer electronic device 811 with an integrated audio enhancement system 10, 110, 110′, 210, 310, 410. As seen from the figure, the audio enhancement system 10, 110, 110′, 210, 310, 410 levels out the frequency response, while extending the bass range (e.g. lower frequency range) of the frequency response. These improvements in audio output 814 from the consumer electronic device 811 may be advantageous for improving user experience, decreasing part to part variability, and for standardizing audio applications that run on the consumer electronic device 811.

FIG. 5c shows a comparison between an impulse response test of the audio output 814 of the consumer electronic device 811 with and without an integrated audio enhancement system 10, 110, 110′, 210, 310, 410. The figure shows two impulse responses 823, 824, offset from each other along the vertical axis for clarity. The response time, measureable in milliseconds, is shown along the horizontal axis. The amplitude of an audio test input (e.g. a microphone) placed in the sound field of the consumer electronic device 811 is shown along the vertical axis. The initial impulse response 823 for the consumer electronic device 814 demonstrates a less than ideal curve. The enhanced impulse response 824 shows a more ideal response for the consumer electronic device 811.

Analyzing the frequency response, impulse response, etc. of the consumer electronic device 811 may be used to calculate an acoustic signature for the consumer electronic device. Optimal compensating parameters for the audio enhancement system 10, 110, 110′, 210, 310, 410 can be derived from the acoustic signature. The acoustic signature can then be compensated for in the audio enhancement system 10, 110, 110′, 210, 310, 410 to produce an enhanced audio output 821. The acoustic signature may also be used to derive one or more parameters in the audio enhancement system 10, 110, 110′, 210, 310, 410 thus providing another means for compensating for the acoustic signature of the consumer electronic device.

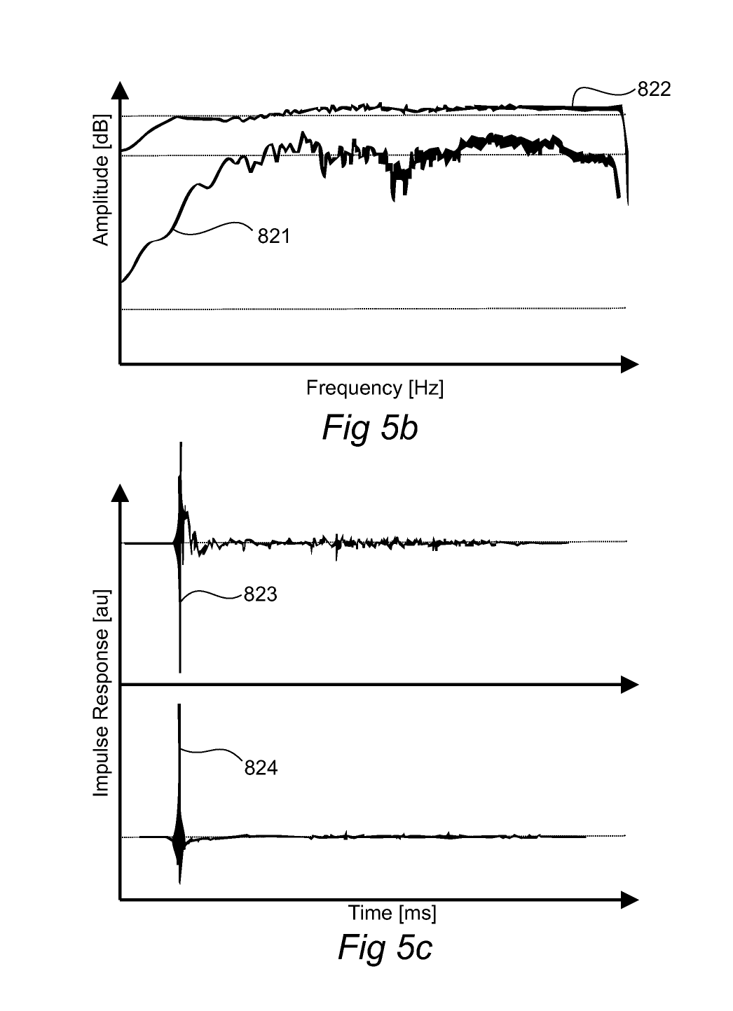

FIGS. 6a and 6b show non-limiting examples of methods 902, 912 for enhancing the audio output from a consumer electronic device.

FIG. 6a shows a method 902 for enhancing audio performance of a consumer electronic device. The method 902 includes determining a set of parameters 904 for a configurable audio processing system, optimizing and/or formulating the audio processing system with the parameters 906, and integrating the optimized audio processing system into the consumer electronic device 908.

The parameters may be determined and/or optimized by analyzing the consumer electronic device in a test chamber (e.g. an anechoic test chamber) including one or more audio sensors, and running a configuration algorithm to pre-configure and determine the optimal parameters for the configurable audio processing system in combination with the analysis. The parameters may be iteratively determined through repetition of the analysis process.

A non-limiting example of a method for enhancing audio performance of a consumer electronic device (CED) 811 includes placing the consumer electronic device 811 including an audio signal source, one or more transducers, and an audio enhancement system (AES) 10, 110, 110′, 210, 310, 410 into an anechoic chamber with a plurality of audio sensors (e.g. microphones) spatially and optionally strategically arranged within the anechoic chamber and/or on or within the CED 811 (e.g. a microphone on a handset CED 811). A range of test audio signals (e.g. impulse signals, frequency sweeps, music clips, pseudo-random data streams, etc.) may be played on the consumer electronic device 811 and monitored with the audio sensors. In an initial test, the audio enhancement system 10, 110, 110′, 210, 310, 410 may substantially include an uncompensated distortion function (a null state whereby the audio enhancement system 10, 110, 110′, 210, 310, 410 is configured so as to not substantially affect the audio signal pathway through the CED 811). The uncompensated distortion function may act to minimally affect the acoustic signature of the CED 811 during the initial testing procedures.

The effect of the CED 811 on the test audio signals can be measured by the audio sensors. The CED 811 acoustic signature can be estimated from cross correlation of the test audio signals with the corresponding measured signals from the audio sensors. To further improve the estimation process, the acoustic signature of every element in the anechoic chamber may be estimated (including any audio sensors, the mounting apparatus of the consumer electronic device, the effect of any test leads or cables on the consumer electronic device, etc.) and subsequently compensated for in the above analysis. Thus a more true representation of the acoustic signature as well as the acoustic responses of the CED 811 to the full gamut of test audio signals may be obtained.

The audio enhancement system 10, 110, 110′, 210, 310, 410 transfer functions may then be parametrically configured to compensate for the acoustic signature of the CED 811. One, non-limiting approach for calculating the audio enhancement system transfer function(s) from the acoustic signature of the CED 811 is to implement a time domain inverse finite impulse response (FIR) filter based upon the estimated acoustic signature of the CED 811. This may be implemented by performing one or more convolutions of the AES 10, 110, 110′, 210, 310, 410 transfer functions with the acoustic responses of the CED 811 to the audio input signals. An averaging algorithm may be used to optimize the transfer function(s) of the AES 10, 110, 110′, 210, 310, 410 from the outputs measured across multiple sources and/or multiple test audio signals.

In one non-limiting example, the compensation transfer function may be calculated from a least squares (LS) time-domain filter design approach. If c(n) is the system response to be corrected (such as the output of an impulse response test) and a compensating filter is denoted as h(n), then one can construct C, the convolution matrix of c(n), as outlined in equation 2:

$$C = [ \begin{matrix}c ( 0 ) & & 0 \\ ⋮ & ⋱ & ⋮ \\ c ( {N}_{c} - 1 ) & ⋱ & c ( 0 ) \\ ⋮ & ⋱ & ⋮ \\ 0 & & c ( {N}_{c} - 1 )\end{matrix} ] \qquad [ equation 2 ]$$

where Nₒ is the length of the response c(n). C has a number of columns equal to the length of h(n) with which the response is being convoluted. Assuming the sequence h has length denoted by Nₕ then the number of rows of C is equal to (Nₕ+Nₒ−1). Then, using a deterministic least squares (LS) approach to compare against a desired response, (in a non-limiting example, defined as the Kronecker delta function δ(n−m) one can express the LS optimal inverse filter as outlined in equation 3:

h(n)=(C^{T}C)⁻¹C^{T}aₘ [equation 3]

where aₘ(n) is a column vector of zeroes with 1 in the mth position to create the modeling delay. The compensation filter h(n) can then be computed from equation 3 using a range of computational methods.

In another non-limiting example, the parametrically configurable transfer function(s) of the AES 10, 110, 110′, 210, 310, 410 may be iteratively determined by subsequently running test audio signals on the CED 811 with the updated transfer function(s) and monitoring the modified acoustic signature of the CED 811 with the audio sensors. A least squares optimization algorithm may be implemented to iteratively update the transfer function(s) between test regiments until an optimal modified acoustic signature of the CED 811 is obtained. Other, non-limiting examples of optimization techniques include non-linear least squares, L2 norm, averaged one-dependence estimators (AODE), Kalman filters, Markov models, back propagation artificial neural networks, Baysian networks, basis functions, support vector machines, k-nearest neighbors algorithms, case-based reasoning, decision trees, Gaussian process regression, information fuzzy networks, regression analysis, self-organizing maps, logistic regression, time series models such as autoregression models, moving average models, autoregressive integrated moving average models, classification and regression trees, multivariate adaptive regression splines, and the like.

Due to the spatial nature of the acoustic signature of a CED 811, the optimization process may be configured so as to minimize error between an ideal system response and the actual system response as measured at several locations within the sound field of the CED 811. The multi-channel data obtained via the audio sensors may be analyzed using sensor fusion approaches. In many practical cases, the usage case of the CED 811 may be reasonably well defined (e.g. the location of the user with respect to the device, the placement of the device in an environment, etc.) and thus a suitable spatial weighting scheme can be devised in order to prioritize the audio response of the CED 811 in certain regions of the sound field that correspond to the desired usage case. In one, non-limiting example, the acoustic response within the forward facing visual range of a laptop screen may be favored over the acoustic response as measured behind the laptop screen during such tests. In this way, a more optimal acoustic enhancement system 10, 110, 110′, 210, 310, 410 may be formulated to suit a particular usage case for the CED 811.

FIG. 6b shows a non-limiting example of a method 912 for enhancing audio in a consumer electronic device. The method 912 includes integrating a configurable audio enhancement system into a consumer electronic device 914, testing the consumer electronic device during the manufacturing, validation or final testing process 916, and updating the audio enhancement system within the consumer electronic device 918.

The consumer electronic device may be tested 916 in an automated test cell. The automated test cell and/or a connected processor may run a diagnostic test on the consumer electronic device and record audio output from the device obtained during the diagnostic test. An update to the audio enhancement system may be generated using data obtained from the diagnostic test, and the automated test cell may update the audio enhancement system on the consumer electronic device 918.

The method 912 may include hardcoding the optimized audio processing system into a hardware descriptive language (HDL) implementation. An HDL implementation may be advantageous for simplifying integration of the audio processing and enhancement system into existing processors and/or hardware on the consumer electronic device. An HDL implementation may also be advantageous for encrypting and protecting the parameters in the audio processing system.

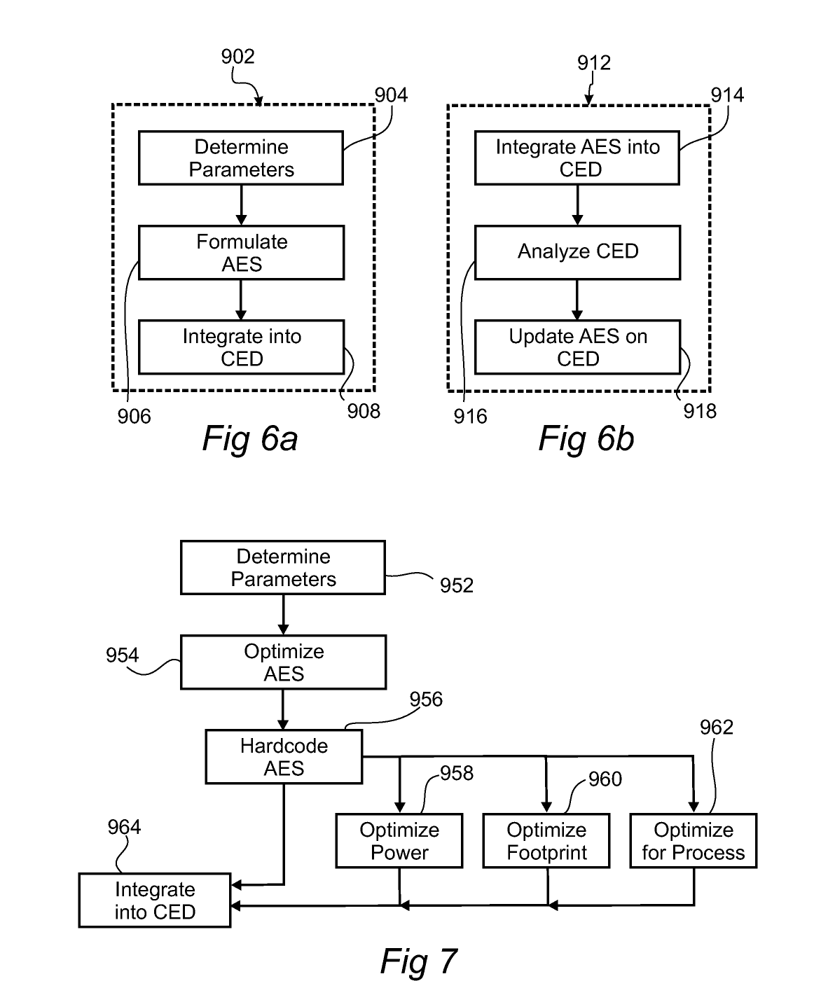

FIG. 7 shows a non-limiting example of a method for integrating an audio enhancement system (AES) into a consumer electronic device. The method includes determining the parameters of the audio enhancement system 952, optimizing the audio enhancement system 954, hard coding the audio enhancement system 956 into a hardware descriptive language (HDL) implementation, and integrating the audio enhancement system into a consumer electronic device 964. The method may include a step of optimizing the power usage of the AES 958, optimizing the footprint of the AES 960, and/or optimizing the hardcoded implementation for a given semiconductor fabrication process 962.

The method may include optimizing the HDL implementation for reduced power 958, reduced footprint 960, or for integration into a particular semiconductor manufacturing process (e.g. 13 nm-0.5 μm CMOS, CMOS-Opto, HV-CMOS, SiGe BiCMOS, etc.) 962. This may be advantageous for providing an enhanced audio experience for a consumer electronic device without significantly impacting power consumption or adding significant hardware or cost to an already constrained device.

It will be appreciated that additional advantages and modifications will readily occur to those skilled in the art. Therefore, the disclosures presented herein and broader aspects thereof are not limited to the specific details and representative embodiments shown and described herein. Accordingly, many modifications, equivalents, and improvements may be included without departing from the spirit or scope of the general inventive concept as defined by the appended claims and their equivalents.

1. An audio enhancement system for improving audio performance of a consumer electronic device with an acoustic signature and a transducer, comprising:
a parametrically configurable processing (PCP) block; and
a digital driver (DD) block in signal communication with the PCP block and the transducer of the consumer electronic device;
wherein the PCP block is configured to receive an input audio signal from the consumer electronic device and to form an enhanced signal from the received input audio signal,
wherein the DD block is configured to receive the enhanced signal from the PCP block, to derive an audio output signal from the enhanced signal, and to output the audio output signal to the transducer, and
wherein the PCP block is configured to substantially compensate for the acoustic signature of the consumer electronic device with the enhanced signal.

2. The audio enhancement system in accordance with claim 1, wherein the PCP block is further configured to superimpose psychoacoustic effects and/or real bass enhancement onto the input audio signal.

3. The audio enhancement system in accordance with claim 1, wherein the PCP block is further configured to integrate an ambient environmental characteristic into, and/or superimpose an ambient sound effect onto the input audio signal.

4. The audio enhancement system in accordance with claim 1, wherein the PCP block is further configured to accept one or more parameters, which are preconfigured to depend at least partially upon the acoustic signature of the consumer electronic device.

5. The audio enhancement system in accordance with claim 4, wherein the PCP block is parametrically configurable with the one or more parameters.

6. The audio enhancement system in accordance with claim 1, wherein the DD block comprises a pulse width modulator.

7. The audio enhancement system in accordance with claim 1, further comprising an asynchronous sample rate conversion (ASRC) block connected between the input audio signal and the PCP block.

8. The audio enhancement system in accordance with claim 1, further comprising an asynchronous sample rate conversion (ASRC) block connected between the PCP block and the DD block.

9. The audio enhancement system in accordance with claim 8, wherein the ASRC block is configured to operate in two or more power and/or performance states.

10. The audio enhancement system in accordance with claim 9, wherein the audio enhancement system is integrated into an application specific integrated circuit on the consumer electronic device.

11. The audio enhancement system in accordance with claim 10, wherein the audio enhancement system is implemented in all-digital hardware.

12. The audio enhancement system in accordance with claim 1, wherein the DD block comprises a class D amplifier.

13. The audio enhancement system in accordance with claim 4, wherein the DD block performs a diagnostic function to analyze the transducer, generate a feedback signal dependent upon the analysis of the transducer, and generate the one or more parameters dependent upon the feedback signal.

14. The audio enhancement system in accordance with claim 1, wherein the PCP block is configured to superimpose a personalized greeting, location specific information, and/or audio watermarks onto the input audio signal.

15. A method for enhancing audio experience of a consumer electronic device having an acoustic signature, comprising:
determining the acoustic signature of the consumer electronic device;
formulating an audio enhancement system from the acoustic signature; and
integrating the audio enhancement system into the consumer electronic device.

16. The method in accordance with claim 16, further comprising adding psychoacoustic and/or real-bass enhancement functionality to the audio enhancement system.

17. A method for enhancing audio performance of a consumer electronic device, comprising:
integrating an audio enhancement system into the consumer electronic device, wherein the audio enhancement system comprises a parametrically configurable processing block configured to receive an input audio signal from the consumer electronic device and to form an enhanced signal from the received input audio signal;
analyzing the consumer electronic device during a manufacturing, quality control and/or product testing process to determine a set of optimization parameters;
updating the parametrically configurable processing block of the audio enhancement system with the optimization parameters.

18. The method in accordance with claim 17, wherein the step of analyzing is performed in a controlled laboratory environment.

19. The method in accordance with claim 17, wherein the steps of analyzing and updating are performed in an automated test cell.

20. The method in accordance with claim 17, wherein the steps of analyzing and updating are performed iteratively.

21. A system for enhancing an audio output of a consumer electronic device having an acoustic signature and a transducer, the system comprising:
a remote subsystem, comprising a parametrically configured processing (PCP) block, the PCP block configured to accept an input audio signal and produce an enhanced audio signal; and
an integrated subsystem in signal communication with the remote subsystem, comprising a digital driver (DD) block, configured to receive the enhanced audio signal and deliver an output signal to the transducer on the consumer electronic device;
wherein the remote system is implemented remotely from the consumer electronic device, and
wherein the integrated subsystem is implemented in the consumer electronic device.

22. The system in accordance with claim 21, wherein the remote subsystem is implemented in the cloud, on a local server, on a network computer, or on a router.

23. The system in accordance with claim 21, wherein the PCP block is configured to compensate for the acoustic signature of the consumer electronic device.

24. The audio enhancement system in accordance with claim 3, wherein the PCP block is further configured to accept one or more parameters, which are preconfigured to depend at least partially upon the acoustic signature of the consumer electronic device, the ambient environmental characteristic, and/or the ambient sound effect.
